(19) United States
(12) Patent Application Publication
(10) Pub. No.: US 2010/0181578 A1
(43) Pub. Date: Jul. 22, 2010

(54) PACKAGE STRUCTURE

(75) Inventors: Kuo-Hsiung LI, Hsin-Chu (TW); Hui-Hsuan Chen, Hsin-Chu (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: PixArt Imaging Inc., Hsinchu City (TW)

(21) Appl. No.: 12/405,728

(22) Filed: Mar. 17, 2009

(30) Foreign Application Priority Data
Jan. 21, 2009 (TW) 098201189

(51) Int. Cl. H01L 31/12; H01L 31/0203

(52) U.S. Cl. 257/82; 257/E31.121; 257/E31.117; 257/E31.095

(57) ABSTRACT

A package structure is described. A light emitting element and a light sensing element are disposed on a substrate, and are both wrapped by a package layer. Meanwhile, the light emitting element and the light sensing element are separated by a trench of the package layer, such that lights generated by the light emitting element are blocked, thereby reducing the noise interference on the light sensing element and improving the sensing precision of the light sensing element.

### CROSS-REFERENCE TO RELATED APPLICATIONS

This non-provisional application claims priority under 35 U.S.C. § 119(a) on Patent Application No(s). 098201189 filed in Taiwan, R.O.C. on Jan. 21, 2009 the entire contents of which are hereby incorporated by reference.

### BACKGROUND OF THE INVENTION

1. Field of Invention

The present invention relates to a package structure, in particular, to a package structure having a light source and a light source sensor integrated on a circuit board.

2. Related Art

With the rapid development of electronic technology, image sensing has been more and more widely applied, for example, in a digital camera, a biological recognition system, a fingerprint recognizer, an optical mouse, and other electronic products.

In a package structure generally utilized in an image sensing device, the mainly required elements are modularized to facilitate the assembly of the image sensing device in production. The package structure substantially includes a light emitting element, a sensing element, a circuit board, and a package case. The light emitting element and the light sensing element are disposed on the circuit board, and are wrapped on the circuit board by the package case. Meanwhile, the package case has a partition board for separating the light emitting element from the light sensing element on the circuit board, so as to respectively form a light emitting region and a light receiving region. Thereby, lights generated by the light emitting element in projection are blocked by the partition board instead of being delivered to the light sensing element through scattering or diffraction. In this manner, the light sensing element is not interfered by noises from the peripheral lights, and thus the sensitivity thereof is enhanced.

Though the aforementioned package structure is capable of separating the light emitting element from the light sensing element, in the manufacturing of the circuit board and the package case, the partition board of the package case must be disposed corresponding to the positions of the light emitting element and the light sensing element, so as to achieve the purpose of separation. Therefore, the complexity in manufacturing the circuit board and the package case is increased, and the problem that the production/assembly speed of the image sensing device cannot be effectively improved still exists.

Further, another modularized package structure including a substrate with a light emitting element and a light sensing element, a transparent layer, and a coating material layer is also provided. The light emitting element and the light sensing element are wrapped by the transparent layer. The coating material layer is coated on the circuit board and the transparent layer, and is filled between the light emitting element and the light sensing element. The coating material layer is made of a common black plastic material for separating the light emitting element from the light sensing element.

In the package structure described above, though the fabrication of a package case is omitted, a first molding is performed in the manufacturing of the entire structure, so as to form the transparent layer wrapping the light emitting element and the light sensing element. Next, the peripheral residual glue, i.e., a part of the transparent layer, is deflashed. After that, a second molding is performed to form the coating material layer on the transparent layer, and the coating material layer is filled between the light emitting element and the light sensing element. Then, similarly, the peripheral residual glue, i.e., a part of the coating material layer, is deflashed. Finally, a form/singulation process is performed to complete the package structure.

Therefore, the aforementioned package structure is still disadvantageous in requiring a complex fabrication process. Moreover, two processes are performed in order to separate the light emitting element from the light sensing element, which not only prolongs the operation time, but also increases the production cost as more raw materials are needed.

### SUMMARY OF THE INVENTION

Accordingly, the present invention is a package structure adapted to eliminate the problem that in a circuit board having a light emitting element and a light sensing element, lights generated by the light emitting element are directly delivered to the light sensing element through scattering, diffraction, or projection, such that the light sensing element is interfered by the lights and the sensing precision thereof is lowered.

A package structure comprising a substrate and a package layer is provided. The substrate has a light emitting element and a light sensing element. The package layer wraps the light emitting element and the light sensing element, and has a trench for separating the light emitting element from the light sensing element.

A package structure comprising a substrate, a case, and an isolation layer is further provided. The substrate has a light emitting element and a light sensing element. The case, disposed on the substrate, has a partition board for separating the light emitting element from the light sensing element on the substrate, and has two perforations respectively corresponding to the light emitting element and the light sensing element. The isolation layer is disposed on the case, and has two via-holes respectively corresponding to the two perforations of the case.

In the package structure of the present invention, the light emitting element and the light sensing element located on two sides of the substrate are separated from each other by the trench opened on the package layer, such that the lights generated by the light emitting element are blocked and/or reflected by the trench instead of being delivered to one side of the light sensing element, thereby reducing the noise interference on the light sensing element and also improving the sensing precision thereof.

### BRIEF DESCRIPTION OF THE DRAWINGS

The present invention will become more fully understood from the detailed description given herein below for illustration only, and thus are not limitative of the present invention, and wherein:

FIG. 1 is a schematic structural view of a first embodiment of the present invention;

FIG. 2 is a schematic top view of the first embodiment of the present invention;

FIG. 3A is a schematic structural view of the first embodiment of the present invention, in which a trench is formed with a rough surface;

FIG. 3B is a schematic top view of the first embodiment of the present invention, in which the trench surrounds a light emitting element;

FIG. 3C is a schematic top view of the first embodiment of the present invention, in which the trench surrounds the light emitting element;

FIG. 4A is a schematic structural view of a second embodiment of the present invention;

FIG. 4B is a schematic structural view of the second embodiment of the present invention, in which a trench has an isolation layer;

FIG. 5 is a schematic structural view of the second embodiment of the present invention, in which a plurality of isolation layers is provided;

FIG. 6 is a schematic structural view of the first embodiment of the present invention, in which a cover is provided;

FIG. 7 is a schematic structural view of the second embodiment of the present invention, in which a cover is provided; and

FIG. 8 is a schematic structural view of a third embodiment of the present invention.

### DETAILED DESCRIPTION OF THE INVENTION

A package structure provided by the present invention is a modularized package structure of an image sensing device used in a digital camera, a biological recognition system, a fingerprint recognizer, an optical mouse, and other electronic products.

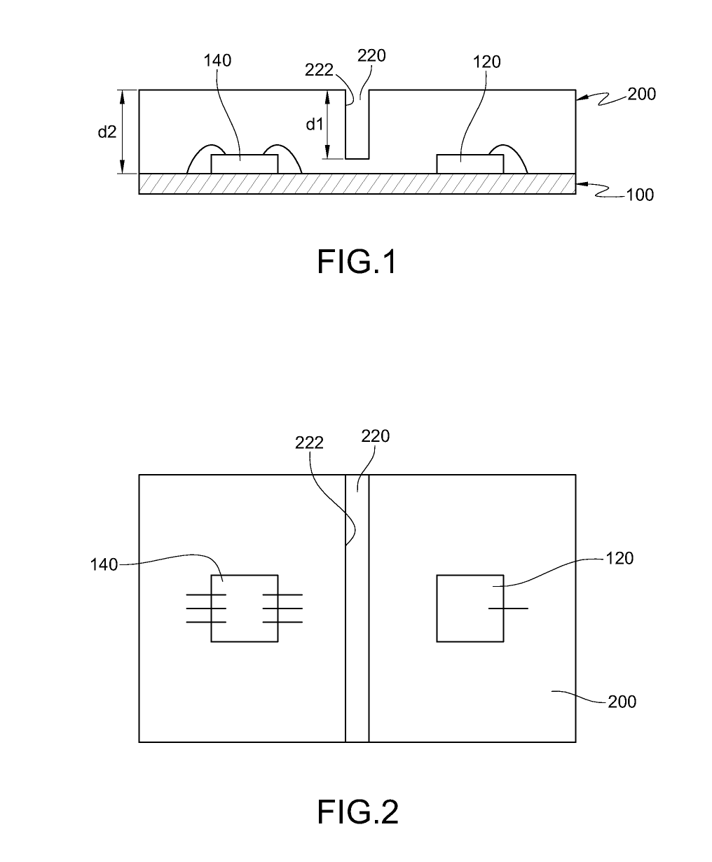

FIGS. 1 and 2 are respectively a schematic structural view and a schematic top view of a first embodiment of the present invention. The package structure according to the first embodiment of the present invention comprises a substrate 100 and a package layer 200. The substrate 100 is a conventional circuit board mounted with a circuit such as an integrated circuit board or a printed circuit board, or is a lead frame. A light emitting element 120 and a light sensing element 140 are disposed on the substrate 100, the light emitting element 120 is a light emitting diode (LED), a vertical cavity surface emitting laser (VCSEL), an edge-emitting laser (EELD), or other elements capable of emitting lights, and the light sensing element 140 is a charge-coupled device (CCD), a complementary metal-oxide semiconductor (CMOS), or other sensors formed by image sensing chips. The light emitting element 120 and the light sensing element 140 are disposed on the substrate 100 by means of wire bonding, surface mount technology (SMT), die bonding, or flip-chip technology, and are respectively electrically connected to the substrate 100.

The package layer 200 is disposed on the substrate 100, and wraps the light emitting element 120 and the light sensing element 140. In this embodiment, the package layer 200 is molded on the substrate 100. A material of the package layer 200 is epoxy resin, silicon resin, or other highly transmissive materials. The package layer 200 has a trench 220 opened on a surface of the package layer 200 and extending towards the substrate 100, and the trench 220 is disposed between the light emitting element 120 and the light sensing element 140, for separating the light emitting element 120 from the light sensing element 140. Thereby, the lights generated by the light emitting element 120 are blocked, for example, absorbed and/or reflected by the trench 220, instead of being delivered to the light sensing element 140 through scattering, diffraction, or direct projection in the package layer 200. In this manner, the noise interference on the light sensing element 140 is reduced, and the sensing precision and sensitivity of the light sensing element 140 are improved.

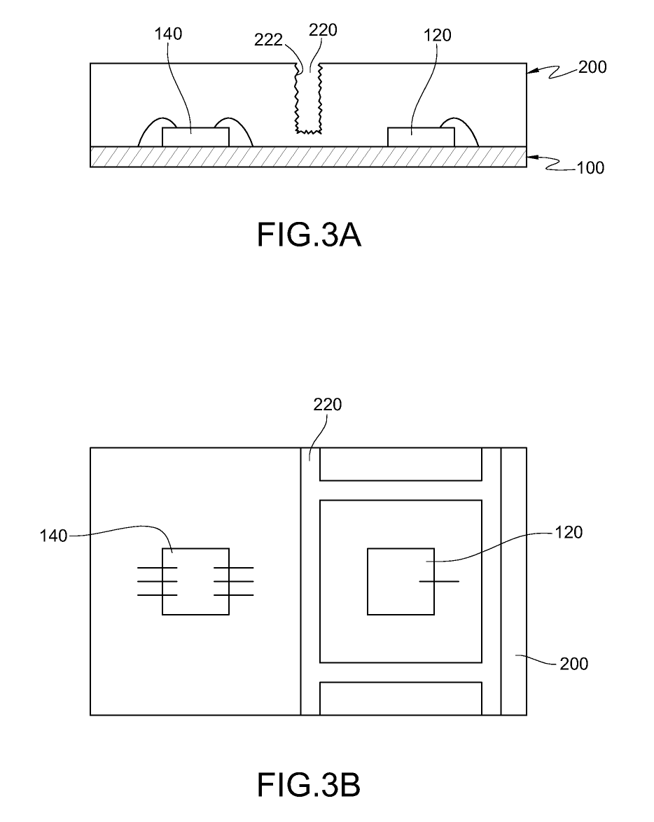

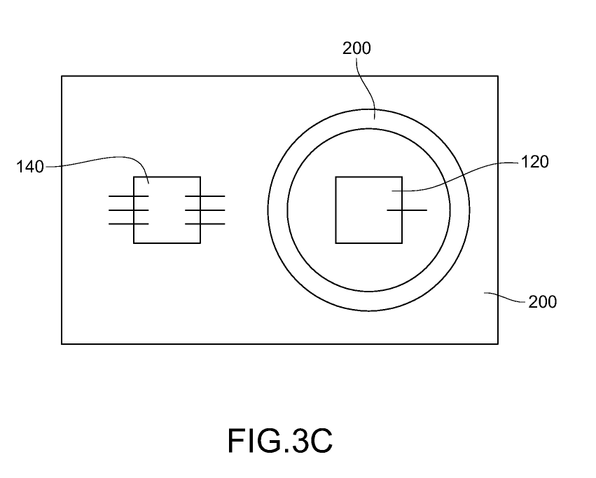

Therefore, referring to FIG. 3A, a wall 222 of the trench 220 is formed with a rough surface, so that the refraction or total reflection degree of the lights generated by the light emitting element 120 at the trench 220 is increased, and thus the probability of the lights delivered to the light sensing element 140 is lowered. Meanwhile, referring to FIGS. 3B and 3C, the trench 220 may surround the light emitting element 120, so that the traveling direction of the lights generated by the light emitting element 120 is limited, and the lights cannot be directly delivered to the light sensing element 140.

Further referring to FIG. 1, a depth d1 of the trench 220 is determined according to the method of forming the trench 220 on the package layer 200. When the trench 220 is formed during the molding of the package layer 200 on the substrate 100, the depth d1 of the trench 220 is equal to or smaller than a thickness d2 of the package layer 200. When the trench 220 is opened on the package layer 200 through an additional process, for example, cut with a mechanical diamond cutter, after the package layer 200 is disposed on the substrate 100, in order to prevent the substrate 100 from being damaged during the process, the depth d1 of the trench 220 is made smaller than the thickness d2 of the package layer 200. Meanwhile, when the depth d1 of the trench 220 is smaller than the thickness d2 of the package layer 200, the depth d1 must match with a light emitting angle of the light emitting element 120, so as to block the lights generated by the light emitting element 120 from being delivered to the light sensing element 140. Alternatively, the light emitting element 120 is raised on the substrate 100, such that the lights generated by the light emitting element 120 are blocked by the trench 220 (not shown).

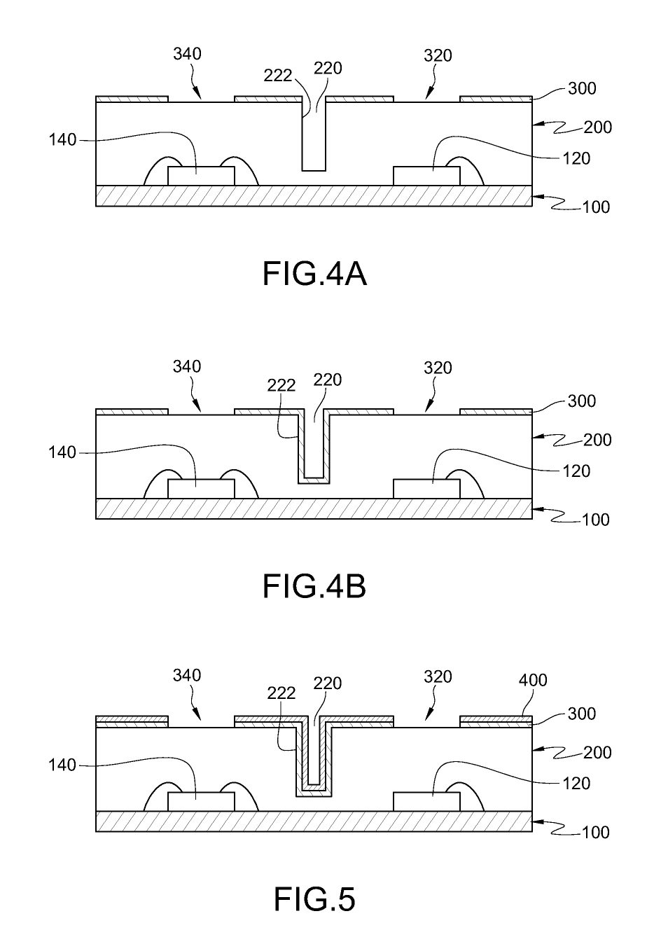

FIGS. 4A and 4B are schematic structural views of a second embodiment of the present invention. The second embodiment of the present invention provides a structure similar to that of the first embodiment, and the differences there-between are described as follows. In the package structure according to the second embodiment of the present invention, after the package layer 200 is disposed on the substrate 100 and the trench 220 is formed to separate the light emitting element 120 from the light sensing element 140, an isolation layer 300 is disposed on the package layer 200. The isolation layer 300 has two via-holes 320 and 340 respectively corresponding to the light emitting element 120 and the light sensing element 140. The via-hole 320 is formed to project the lights generated by the light emitting element 120 out of the package structure, and the lights are then reflected or refracted into the other via-hole 340 and is received by the light sensing element 140.

The isolation layer 300 is made of a light reflecting and/or absorbing material, for example, a deep color plate, an ink, a plate doped with a light reflecting and/or absorbing toner, or an ink doped with a light reflecting and/or absorbing toner. Meanwhile, the isolation layer 300 is disposed on the package layer 200 by means of transferring, adhering, coating, spraying, or filming. According to different forming manners, the isolation layer 300 is only formed on the surface of the package layer 200, or formed on the wall 222 of the trench 220 at the same time. Referring to FIG. 4A, for example, a reflecting plate is adhered to the surface of the package layer 200. Alternatively, referring to FIG. 4B, a color ink (for example, a black ink) is sprayed on the surface of the package layer 200 and the wall 222 of the trench 220.

Therefore, by using the isolation layer 300, the lights generated by the light emitting element 120 can only be projected out of the package layer 200 through the via-hole 320, and the scattered or diffracted stray lights among the lights are reflected and/or absorbed by the isolation layer 300 in the package layer 200. Meanwhile, referring to FIG. 5, a plurality of isolation layers 300 and 400 with different properties is stacked on the package layer 200, for example, the isolation layer 300 is made of a material capable of reflecting the lights generated by the light emitting element 120, and the other isolation layer 400 is made of a material capable of absorbing or reflecting the lights having other wavelengths. Therefore, when the light emitting element 120 generates a light, the light is reflected and blocked by the isolation layer 300 and the trench 220, and can only be projected out of the package layer 200 through the via-hole 320. When the light is reflected or refracted into the via-hole 340, lights having other wavelengths from outside the package layer 200 are reflected or absorbed by the isolation layer 400, so as to lower the interference of the external lights on the light sensing element 140, thereby improving the sensing precision and sensitivity of the light sensing element 140.

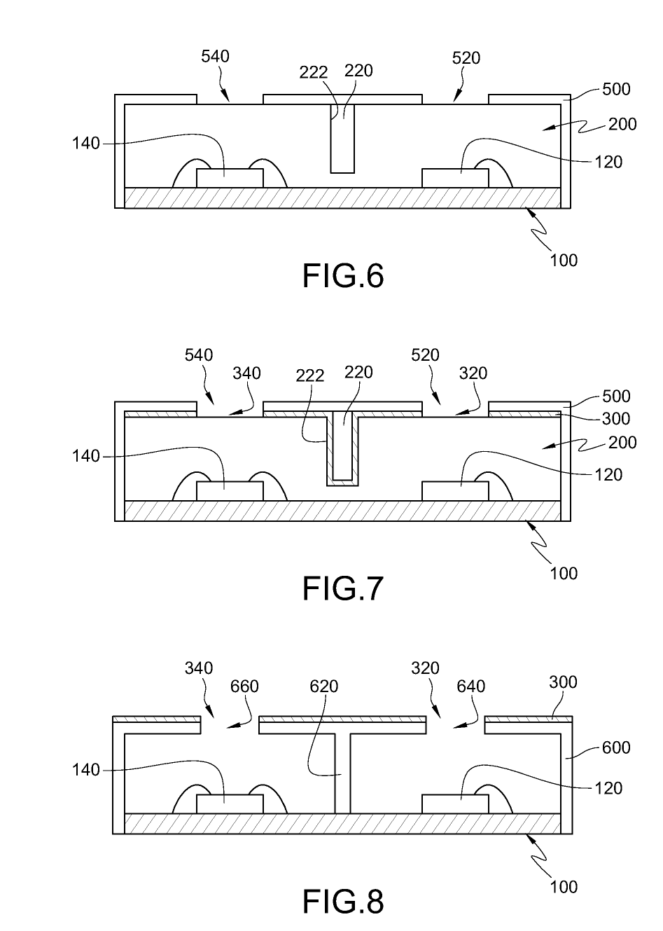

Referring to FIGS. 6 and 7, in the first and the second embodiment of the present invention, a cover 500 is further formed on the package layer 200 and the isolation layer 300, respectively. The cover 500 has two through-holes 520 and 540 respectively corresponding to the light emitting element 120 and the light sensing element 140, such that the lights generated by the light emitting element 120 are projected out of the package layer 200 through the via-hole 320 of the isolation layer and the through-hole 520 of the cover. Meanwhile, the lights, refracted or reflected into the package layer 200 through the through-hole 540 and the via-hole 340, are received by the light sensing element 140. The cover 500 is used for isolating the lights from outside the package layer, so as to reduce the noise interference of the external lights on the light sensing element 140.

FIG. 8 is a schematic structural view of a third embodiment of the present invention. The package structure according to the third embodiment of the present invention comprises a substrate 100, a case 600, and an isolation layer 300. A light emitting element 120 and a light sensing element 140 are electrically disposed on the substrate 100. The case 600 is disposed on the substrate 100, and has a partition board 620 for separating the light emitting element 120 from the light sensing element 140, so as to prevent the lights generated by the light emitting element 120 from being directly delivered to the light sensing element 140. The case 600 has two perforations 640 and 660 respectively corresponding to the light emitting element 120 and the light sensing element 140, such that the lights generated by the light emitting element 120 are projected out of the case 600 through the perforation 640, and the lights reflected or refracted into the case 600 through the perforation 660 are received by the light sensing element 140.

The isolation layer 300 is disposed on the case, and has two via-holes 320 and 340 respectively corresponding to the perforations 640 and 660. The isolation layer 300 is used to block or reflect the sunlight or other stray lights outside the case 600, so as to prevent the light sensing element 140 from being interfered by the noises. Therefore, the types of lights capable of being isolated by the isolation layer 300 and the case 600 are disposed in compensating forms. For example, when the case 600 is used to block the lights generated by the light emitting element 120, the isolation layer 300 may employ a toner capable of absorbing the wavelength of the sunlight, and is disposed on the case 600 by means of transferring, adhering, coating, spraying, or filming. In this manner, the lights generated by the light emitting element 120 can only be projected out of the case 600 through the perforation 640 and the via-hole 320, and then reflected or refracted into the case through the via-hole 340 and the perforation 660, such that the light sensing element 140 may only receive the lights generated by the light emitting element 120 as much as possible, thereby improving the sensing precision of the light sensing element.

In the package structure of the present invention, a trench is opened on the package layer formed on the substrate, so as to separate the light emitting element from the light sensing element on the substrate, such that the lights generated by the light emitting element cannot be directly delivered to the light sensing element, thereby reducing the noise interference on the light sensing element and improving the sensing precision and sensitivity of the light sensing element. Through the trench opened on the package layer, the light emitting element is effectively separated from the light sensing element. As a result, the complex process in the conventional art is simplified, and the demand of raw materials in the production is also reduced, thus enhancing the production performance.

In addition, in the package structure of the present invention, through the isolation layer, lights having specific wavelengths are selectively isolated. Meanwhile, the isolation and blocking strengths of the trench, the cover, and the case on the lights generated by the light emitting element and the lights outside the package structure are further enhanced.

What is claimed is:

1. A package structure, comprising:
a substrate, having a light emitting element and a light sensing element; and
a package layer, for wrapping the light emitting element and the light sensing element, and having a trench for separating the light emitting element from the light sensing element.

2. The package structure according to claim 1, wherein a surface of the trench is a plane.

3. The package structure according to claim 1, wherein a surface of the trench is a rough surface.

4. The package structure according to claim 1, wherein the trench is disposed between the light emitting element and the light sensing element.

5. The package structure according to claim 4, wherein the trench extends from a surface of the package layer to the substrate, for interrupting a light transmission path between the light emitting element and the light sensing element in the package layer.

6. The package structure according to claim 1, wherein the trench surrounds the light emitting element.

7. The package structure according to claim 1, wherein the package layer has a thickness, and the trench has a depth not larger than the thickness.

8. The package structure according to claim 1, further comprising an isolation layer, disposed on the package layer and having two via-holes respectively corresponding to the light emitting element and the light sensing element.

9. The package structure according to claim 8, wherein the isolation layer is doped with a toner.

10. The package structure according to claim 8, wherein the isolation layer is disposed on the package layer by means of transferring, adhering, coating, spraying, or filming.

11. The package structure according to claim 1, further comprising a cover, covered on the package layer and having two through-holes respectively corresponding to the light emitting element and the light sensing element.

12. A package structure, comprising:
a substrate, having a light emitting element and a light sensing element;
a case, disposed on the substrate, having a partition board for separating the light emitting element from the light sensing element, and having two perforations respectively corresponding to the light emitting element and the light sensing element; and
an isolation layer, disposed on the case, and having two via-holes respectively corresponding to the two perforations.

13. The package structure according to claim 12, wherein the isolation layer is doped with a toner.

14. The package structure according to claim 12, wherein the isolation layer is disposed on the package layer by means of transferring, adhering, coating, spraying, or filming.
